(19) United States
(12) Patent Application Publication
(10) Pub. No.: US 2013/0256909 A1
(43) Pub. Date: Oct. 3, 2013

(54) PATTERNED ADHESIVE TAPE FOR BACKGRINDING PROCESSES

(71) Applicants: Dingying Xu, Chandler, AZ (US); Xavier F. Brun, Chandler, AZ (US)

(72) Inventors: Dingying Xu, Chandler, AZ (US); Xavier F. Brun, Chandler, AZ (US)

(21) Appl. No.: 13/992,511

(22) PCT Filed: Sep. 8, 2011
(86) PCT No.: PCT/US11/50835

§ 371 Date: Jun. 7, 2013

(51) Int. Cl. H01L 21/82; C09J 7/02

(52) U.S. Cl. CPC H01L 21/82; C09J 7/02
USPC 257/774; 438/459; 428/138

(57) ABSTRACT

The present disclosure relates to the field of fabricating microelectronic devices, wherein a microelectronic device substrate, such as a microelectronic wafer, may be thinned by a backgrinding process using a patterned adhesive tape that reduces slurry seepage and adhesive contamination. The patterned adhesive tape may comprise a base film and adhesive material patterned on the base film such that an edge or periphery portion of the microelectronic device substrate may contact the adhesive material, but substantially no adhesive material contacts interconnectors formed on the microelectronic device substrate.

### BACKGROUND

Embodiments of the present description generally relate to the field of microelectronic device fabrication and, more particularly, to thinning of microelectronic wafers with a backgrinding process.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 illustrates a microelectronic device substrate having a plurality of microelectronic dice on an active surface thereof, as known in the art.

FIG. 2 illustrates a side cross-sectional view of an adhesive tape applied over an active surface of a microelectronic device substrate prior to a backgrinding process, wherein an adhesive material of the adhesive tape substantially encapsulates interconnectors disposed on the active surface of the microelectronic device substrate, as known in the art.

FIG. 3 illustrates a side cross-sectional view of the structure of FIG. 2 after the backgrinding process, as known in the art.

FIG. 4 illustrates a side cross-sectional view of an adhesive tape applied over an active surface of a microelectronic device substrate, wherein an adhesive material of the adhesive tape substantially encapsulates an upper portion of interconnectors disposed on the active surface of the microelectronic device substrate (illustrated after the backgrinding process), as known in the art.

FIG. 5 illustrates a side cross-sectional view of an adhesive tape applied over an active surface of a microelectronic device substrate, wherein an adhesive material of the adhesive tape contacts a top portion of the interconnectors disposed on the active surface of the microelectronic device substrate (illustrated after the backgrinding process), as known in the art.

FIGS. 6 and 7 illustrate oblique views of contamination resulting from the use of known adhesive tapes, as known in the art.

FIG. 8 illustrates a film-side view of an adhesive tape according to an embodiment of the present description.

FIG. 9 illustrates an adhesive-side view of the adhesive tape of FIG. 8, according to an embodiment of the present description.

FIG. 10 illustrates a side cross-sectional view of an adhesive tape, according to an embodiment of the present description applied over an active surface of a microelectronic device substrate.

FIG. 11 illustrates a side cross-sectional view of the inset 10 of FIG. 9, according to an embodiment of the present description.

FIG. 12 is flow diagram of a process of backgrinding a microelectronic device substrate utilizing an adhesive tape according to an embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description relate to the field of fabricating microelectronic devices, wherein a microelectronic device substrate, such as a microelectronic wafer, may be thinned by a backgrinding process using a patterned adhesive tape that reduces slurry seepage and adhesive contamination.

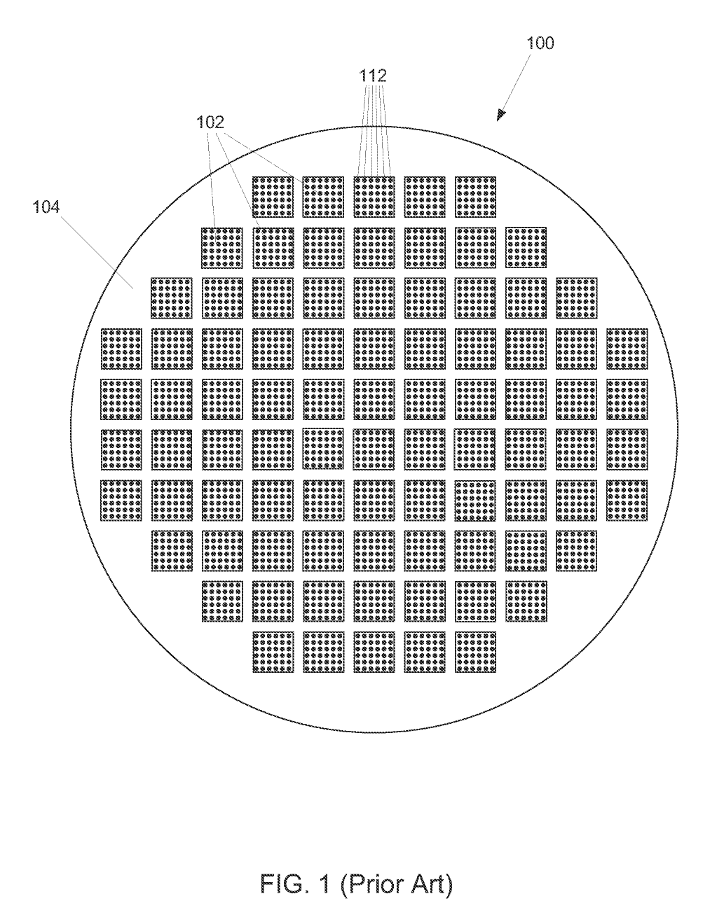

In the production of microelectronic devices, integrated circuitry may be formed in and/or on microelectronic device substrates. As shown in FIG. 1, a single microelectronic device substrate 100, such as a silicon or a silicon-germanium wafer, may contain a plurality of substantially identical integrated circuits (not shown) forming a plurality of microelectronic dice 102, such as microprocessors, chipsets, graphics devices, wireless devices, memory devices, application specific integrated circuits, or the like, on an active surface 104 of the microelectronic device substrate 100. Each of the microelectronic dice 102 may include a plurality of interconnectors 112, such as solder bumps or pillars, which may be in electrical contact with the integrated circuits (not shown) of their respective microelectronic die 102. As will be understood to those skilled in the art, the interconnectors 112 may be used in connect the microelectronic dice 102 to external device or components (not shown). The interconnectors 112 may be any appropriate conductive material, including but not limited to lead/tin alloys, such as tin/lead solder, such as 63% tin/37% lead solder, or lead-free solders, such a pure tin or high tin content alloys (e.g. 90% or more tin), such as tin/bismuth, eutectic tin/silver, ternary tin/silver/copper, eutectic tin/copper, and similar alloys. The fabrication processes for the integrated circuits (not shown) and the interconnectors 112 are well known in the art and will not be discussed herein in the interest of brevity.

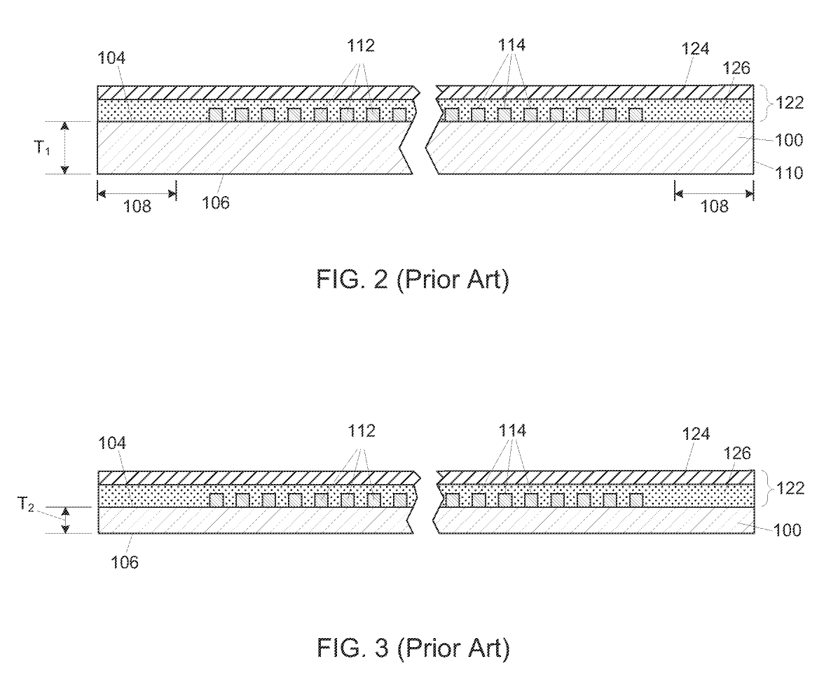

In a wafer backgrinding process (also known as ‘wafer thinning’ or ‘backlapping’), a portion of a back surface 106 (see FIG. 2) of the microelectronic device substrate 100, which opposes the microelectronic device substrate active surface 104, is removed to reduce its thickness (see thickness T₁ for FIG. 2 prior to wafer backgrinding and thickness T₂ in FIG. 3 after wafer backgrinding). Wafer backgrinding is not necessary in the fabrication of the microelectronic dice 102 themselves, but as the desire to make microelectronic devices thinner for use in smart cards, memory sticks, smart phones, portable music players, and other compact electronic products, it has become an advantageous process.

As shown in FIGS. 2 and 3, in the backgrinding process, an adhesive tape 122 may be applied over the microelectronic device substrate active surface 104 prior to the backgrinding process to provide support thereof during the backgrinding process and to protect the microelectronic device substrate 100 from mechanical damage and contamination during the backgrinding process. The adhesive tape 122 may be comprised of a base film 124 and a layer of adhesive material 126. The backgrinding process may be conducted with a backgrinding tool comprising grinding wheels (binded abrasive particle) and a cooling fluid. After the backgrinding process, the microelectronic device substrate 100 is removed from the adhesive tape 122 and sent for further processing.

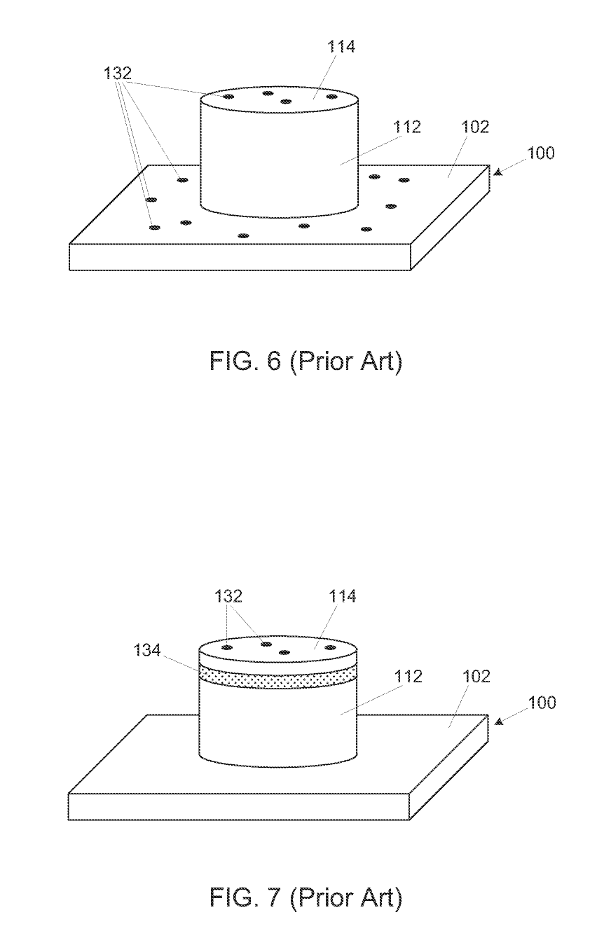

As shown in FIGS. 2 and 3, the attachment of the adhesive tape 122 to the microelectronic device substrate active surface 104 may include the adhesive material 126 substantially encapsulating the interconnectors 112 and substantially covering the microelectronic device substrate active surface 104. This arrangement may be referred to as “full-bump encapsulation”. However, residual adhesive may remain on the microelectronic device substrate active surface 104 and/or interconnectors 112 after the removal of the adhesive tape 122, particularly at a periphery or edge portion 108 proximate an edge 110 of the microelectronic device substrate 100 and in areas of a high density/tight pitch interconnector 112 pattern. Such, residual adhesive can result in defects in the microelectronic dice 102, as will be understood to those skilled in the art. For example, with the full-bump encapsulation of FIGS. 2 and 3, residual adhesive 132 may remain on the microelectronic device substrate active surface 104 around the interconnectors 112, as shown in FIG. 6.

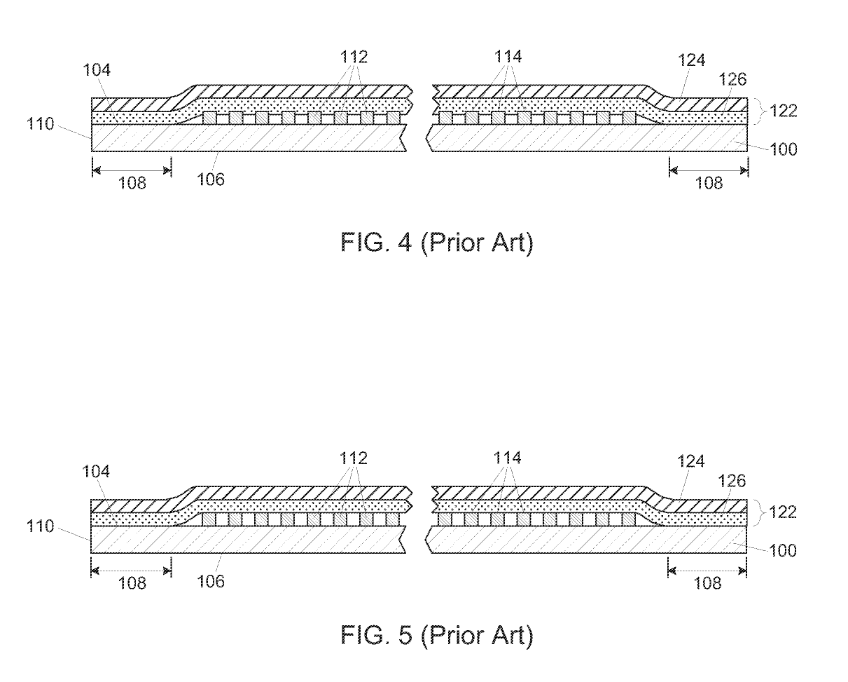

As shown in FIG. 4, in order to reduce residual adhesive contamination, the attachment of the adhesive tape 122 to the microelectronic device substrate active surface 104 may comprise a portion of the adhesive material layer 126 in contact with the microelectronic device substrate edge portion 108 and in contact with a top portion 114 of each interconnector 112 and an upper portion of each interconnector 112 proximate the top portion 114 thereof. This arrangement may be referred to as “partial bump lamination” and may be effectuated by reducing the thickness of the adhesive material layer 126 and/or reducing the adhesive properties of the adhesive material layer 126. Although with the adhesive tape 122 of FIG. 4, it may be possible to reduce or substantially eliminate adhesive residue 132 on the microelectronic device substrate active surface 104, it may result in adhesive residue collar 134 substantially around the interconnector 112, as shown in FIG. 7.

As shown in FIG. 5, in order to further reduce residual adhesive contamination (e.g. elimination of the adhesive residue collar 134 of FIG. 4), the attachment of the adhesive tape 122 to the microelectronic device substrate active surface 102 may comprise a portion of the adhesive material layer 126 in contact with the microelectronic device substrate edge portion 108 and in contact with the top portion 114 of each interconnector 112. This arrangement is referred to as “bump top lamination” and maybe effectuated by further reducing the thickness of the adhesive material layer 126 and/or further reducing the adhesive properties of the adhesive material layer 126.

However, reducing the thickness of the adhesive material layer 126 and/or reducing the adhesive properties of the adhesive material layer 126 may increase the risk of seepage backgrinding slurry between the adhesive material layer 126 and the microelectronic device substrate active surface 104. Backgrinding slurry is a combination of process cooling fluid and particles from the grinding wheel due to wear. Such backgrinding slurry contamination can result in defects in the microelectronic dice 102, as will be understood to those skilled in the art. Moreover, with a desire to increase the number of microelectronic dice 102 (see FIG. 1) on each microelectronic device substrate 100, the space around the microelectronic device substrate edge portion 108 is reduced, which reduces the available contact area between the adhesive material layer 126 and the microelectronic device substrate active surface 104. Thus, the reduction in contact area and the reduction in the adhesive material thickness may significantly increase the risk of seepage of the backgrinding slurry between the adhesive material layer 126 and the microelectronic device substrate active surface 104.

Thus, the prevention of adhesive residue is at odds with the prevention of slurry seepage, because to eliminate the adhesive residue on microelectronic device substrate active surface 102 and/or interconnectors 112, modulus properties of the adhesive material layer 126 have to be increased and, to eliminate the occurrence of slurry seepage, the adhesion properties of the adhesive material layer 126 have to be increased, which means the modulus properties of adhesive material layer 126 have to be decreased. Therefore, the materials property of the adhesive tape 122 cannot be optimally balanced.

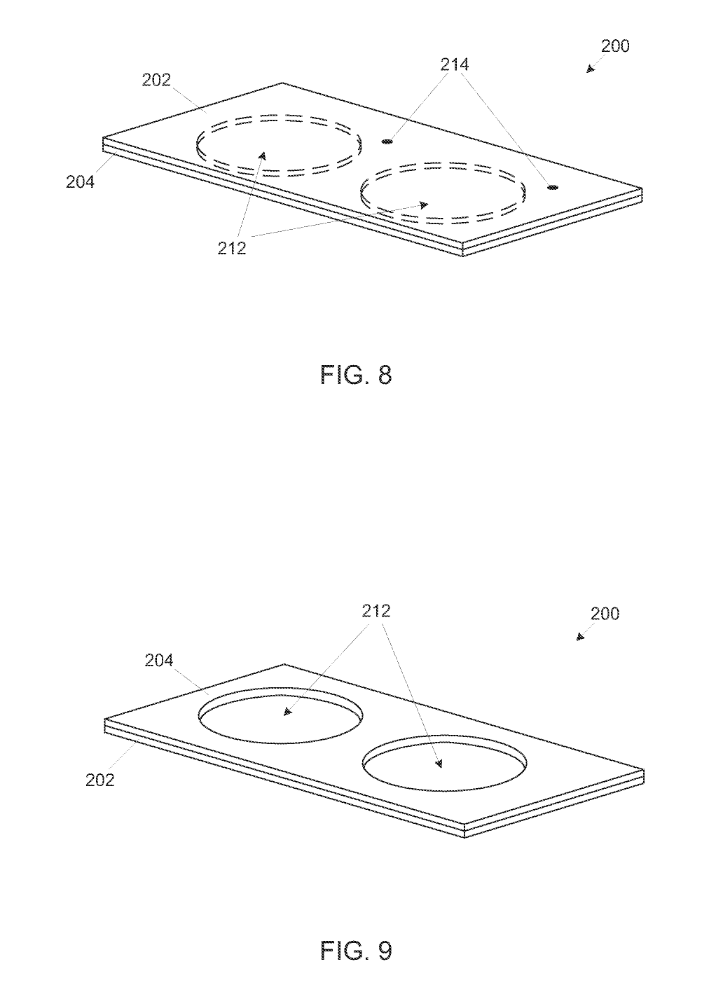

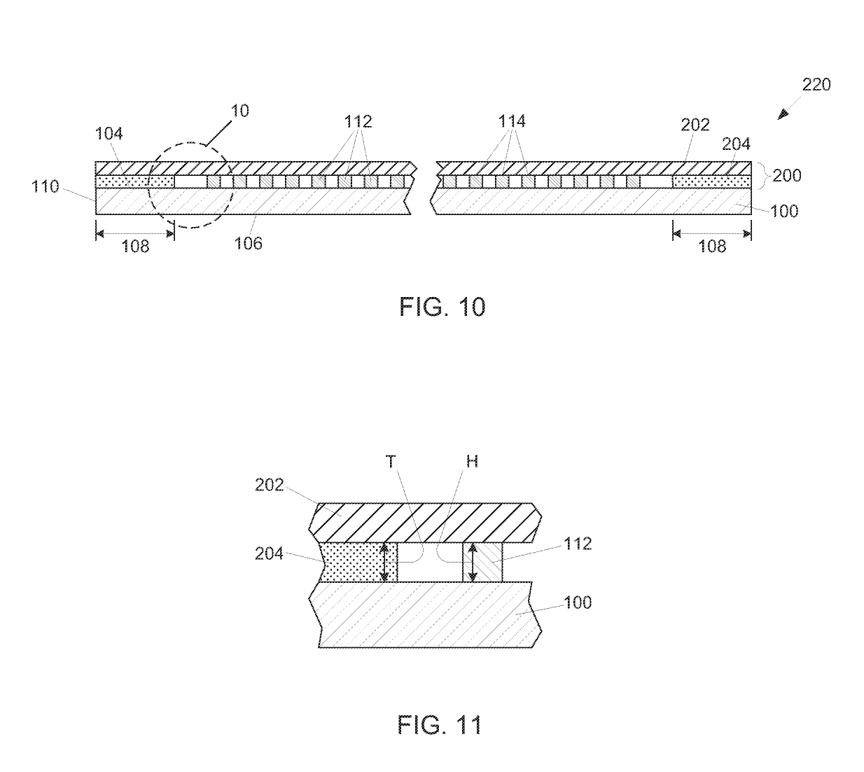

In an embodiment of the present disclosure, an adhesive tape 200 may be comprised of a base film 202 and an adhesive material layer 204 disposed therein on, with at least one opening 212 patterned through an adhesive material layer 204, as shown in FIGS. 8 and 9. As shown in FIG. 10, an intermediate structure 220 may be formed by attaching a microelectronic device substrate 100 to the adhesive material layer 204. The adhesive material layer openings 212 may be patterned, such that the microelectronic device substrate edge portion 108 may contact the adhesive material layer 204, but substantially no portion of the adhesive material layer 204 contacts the interconnectors 112, as shown in FIGS. 10 and 11. Such an arrangement may substantially reduce adhesive residue contamination and/or backgrinding slurry seepage. With regard to adhesive residue contamination reduction, having substantially no portion of the adhesive material layer 204 contacting the interconnectors 112, means that substantially no adhesive residue (see FIGS. 10 and 11) will result on the interconnectors 112. With regard to backgrinding slurry seepage reduction, having the adhesive material layer 204 only contacting the microelectronic device substrate edge portion 108 will allow for the use of the adhesive material layer 204 having of low modulus and high tackiness to achieve an effective seal, which may significantly reduce or prevent slurry seepage during the backgrinding process.

In one embodiment, the opening 212 through the adhesive material layer 204 may be substantially circular. In another embodiment, the opening 212 may be sized such that the microelectronic device substrate edge portion 108 which contacts the adhesive material layer 204 has a width of about equal to or less than about 3 mm. In still another embodiment, the opening 212 may be sized such that the microelectronic device substrate edge portion 108 which contacts the adhesive material layer 204 has a width of about equal to or less than about 2 mm.

The patterned adhesive tape 200 may be comprised of a base film 202, including but not limited to a polymer film, and an adhesive material layer 204, including but not limited to, ultra-violet light curable adhesive. In one embodiment, the adhesive material layer 204 may have an adhesion greater than about 4500 mN/25 mm.

Referring back to FIG. 8, at least one alignment mark 206 may be formed on the base film 202 of the patterned adhesive tape 200 to allow appropriate positioning of the microelectronic device substrate 100 (see FIG. 10) in relation to the openings 212 of the patterned adhesive tape 200.

In order to minimize stress and have sufficient support of the microelectronic device substrate 100 during the backgrinding process, a height H of the interconnector 112 should be approximately the same as a thickness T of the adhesive material layer 204, as shown in FIG. 11. When the interconnector height H is less than the adhesive material layer thickness T, striations may be observed after the backgrinding process at the microelectronic device substrate edge portion 108. Furthermore, micro-cracks may be present on the base film 202 of the patterned adhesive tape 200 near the adhesive material layer openings 212, but not proximate in a center of the microelectronic device substrate 100. Both of these defects are indicative of higher shear stresses induced at the microelectronic device substrate edge portion 108 by the backgrinding process due to insufficient support of the microelectronic device substrate 100 by the patterned adhesive tape 200. When the interconnector height H is greater than the adhesive material layer thickness T, the support of the microelectronic device substrate 100 during backgrinding may reduce the grinding shear stresses. One example of the effect of the adhesive material thickness T relative to the interconnector height H on backgrinding slurry seepage is shown in Table 1, wherein the microelectronic device substrate edge portion 108 width was greater than 100 microns minimum around the entire periphery of a semiconductor wafer.

TABLE 1

| | Inter- | Adhesive | Seepage Incidences |
|---|---|---|---|
| | connector | Material | per Microelectronic |
| | Height in μm | Thickness in μm | Device Sub- |
| | (H) | (T) | strates Processed |
| Experiment 1 | 25 | 30 | 0/11 |
| Experiment 2 | 18.5 | 30 | 6/23 |
| Experiment 3 | 18.5 | 26 | 1/30 |
| Experiment 4 | 18.5 | 15 | 0/6 |

As may be observed from Table 1, higher incidences of slurry seepage are observed when the difference between the adhesive material layer thickness T and the interconnector height H diverges. In one embodiment, the ratio of the adhesive material thickness T to the interconnector height H may be less than about 1.5:1.

In another embodiment, the relationship between adhesive material thickness T and the interconnector height H may be defined by the following equation:

(Adhesive Material Thickness in μm (T)−Interconnector Height in μm (H))≦5 μm

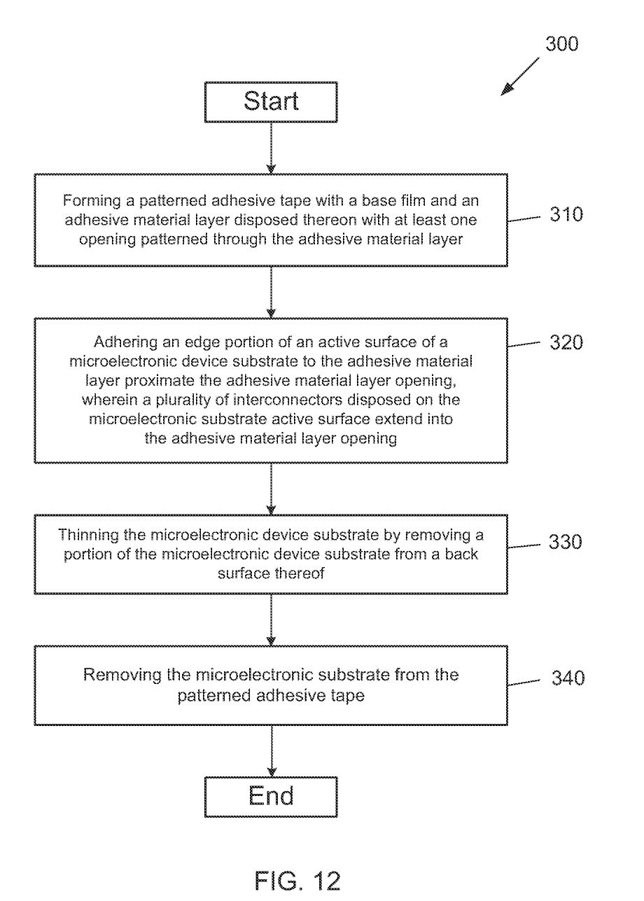

An embodiment of one process of thinning a microelectronic device substrate using the patterned adhesive tape of the present description is illustrated in a flow diagram 300 of FIG. 12. As defined in block 310, an adhesive tape may be formed with a base film and an adhesive material layer disposed thereon with at least one opening patterned through the adhesive material layer. A microelectronic device substrate, having a plurality of interconnectors extending from an active surface thereof, may be attached to the patterned adhesive tape, such that an edge or periphery of the microelectronic device substrate active surface adheres to the adhesive material layer proximate the opening with the plurality interconnectors extending into the adhesive material layer opening, as defined in block 320. As defined in block 330, the microelectronic device substrate may be thinned by removing a portion of the microelectronic device substrate from a back surface thereof The microelectronic device substrate may then be removed from the patterned adhesive tape, as defined in block 340.

It is understood that the subject matter of the present description is not necessarily limited to specific applications illustrated in FIGS. 7-12. The subject matter may be applied to other microelectronic device fabrication applications, as will be understood to those skilled in the art. Furthermore, the subject matter may also be used in any appropriate application outside of the microelectronic device fabrication field.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A patterned adhesive tape comprising:
a base film; and
an adhesive material layer disposed on the base film with at least one opening patterned through the adhesive material layer, wherein the at least one opening is adapted to adhere to an edge portion of a microelectronic device substrate.

2. The patterned adhesive tape of claim 1, wherein the base film comprises a polymer film.

3. The patterned adhesive tape of claim 1, wherein the adhesive material layer comprises an ultra-violet light curable adhesive.

4. The patterned adhesive tape of claim 1, wherein the adhesive material layer has an adhesion greater than about 4500 mN/25 mm.

5. The patterned adhesive tape of claim 1, wherein the at least one opening is substantially circular.

6. An intermediate structure comprising:
a base film;
an adhesive material layer disposed on the base film having at least one opening patterned therethrough; and
a microelectronic device substrate having active surface, a edge portion proximate an edge of the microelectronic device substrate, and a plurality of interconnectors extending from the microelectronic device substrate active surface, wherein the microelectronic device edge portion is adhered to the adhesive material layer and wherein the plurality of interconnectors extend into the at least one opening.

7. The intermediate structure of claim 6, wherein a height of the plurality of interconnectors is approximately the same as a thickness of the adhesive material layer.

8. The intermediate structure of claim 7, wherein a ratio of the adhesive material thickness to the height of the plurality of interconnectors is less than about 1.5:1.

9. The intermediate structure of claim 7, wherein a difference between the adhesive material thickness and the height of the plurality of interconnectors is about equal to or less than 5 μm.

10. The intermediate structure of claim 6, wherein the microelectronic device edge portion adhered to the adhesive material layer has a width of about 3 mm or less.

11. The intermediate structure of claim 10, wherein the microelectronic device edge portion adhered to the adhesive material layer has a width of about 2 mm or less.

12. The intermediate structure of claim 6, wherein the base film comprises a polymer film.

13. The intermediate structure of claim 6, wherein the adhesive material layer comprises an ultra-violet light curable adhesive.

14. The intermediate structure of claim 6, wherein the adhesive material layer has an adhesion greater than about 4500 mN/25 mm.

15. The intermediate structure of claim 6, wherein the at least one opening is substantially circular.

16. The intermediate structure of claim 6, wherein the plurality of interconnectors comprises a plurality of solder bumps.

17. The intermediate structure of claim 6, wherein the base file further includes an alignment mark.

18. A method of thinning a microelectronic device substrate comprising:
forming a patterned adhesive tape with a base film and an adhesive material layer disposed thereon with at least one opening patterned through the adhesive material layer;
adhering an edge portion of an active surface of a microelectronic device substrate to the adhesive material layer proximate the adhesive material layer opening, wherein a plurality of interconnectors disposed on the microelectronic substrate active surface extend into the adhesive material layer opening;
removing a portion of the microelectronic device substrate from a back surface thereof; and
removing the microelectronic device substrate from the patterned adhesive tape.

19. The method of claim 18, wherein removing the portion of the microelectronic device substrate comprises backgrinding the microelectronic device substrate back surface.

20. The method of claim 18, wherein forming the patterned adhesive tape with the base film and the adhesive material layer disposed thereon comprises forming a thickness of the adhesive material layer that is approximately the same as a height of the plurality of interconnectors on the microelectronic device substrate.

21. The method of claim 20, wherein forming the thickness of the adhesive material layer that is approximately the same as a height of the plurality of interconnectors on the microelectronic device substrate comprises forming the adhesive material layer thickness to have a ratio to the height of the plurality of interconnectors on the microelectronic substrate of less than about 1.5:1.

22. The method of claim 20, wherein forming the thickness the adhesive material layer that is approximately the same as a height of the plurality of interconnectors on the microelectronic device substrate comprises a difference between the adhesive material thickness and the interconnector height of about equal to or less than 5 μm.

23. The method of claim 18, wherein the microelectronic device edge portion adhered to the adhesive material layer has a width of about 3 mm or less.

24. The method of claim 18, wherein the microelectronic device edge portion adhered to the adhesive material layer has a width of about 2 mm or less.

25. The method of claim 18, wherein the adhesive material layer has an adhesion greater than about 4500 mN/25 mm.

26. The method of claim 18, wherein adhering the edge portion of the active surface of the microelectronic device substrate to the adhesive material layer proximate the adhesive material layer opening further comprises aligning the microelectronic device substrate to the adhesive material layer opening with at least one alignment mark on the base film.
